(19) United States
(12) Patent Application Publication
(10) Pub. No.: US 2005/0243521 A1
(43) Pub. Date: Nov. 3, 2005

(54) Aligning socket load plates to integral heat spreaders

(76) Inventors: Michael Li, Portland, OR (US); Jiteender P. Manik, Chandler, AZ (US); Tim A. Renfro, Mesa, AZ (US)

Correspondence Address: TROP PRUNER & HU, PC, 8554 KATY FREEWAY, SUITE 100, HOUSTON, TX, 77024, US

(21) Appl. No.: 10/837,180

(22) Filed: Apr. 30, 2004

(51) Int. Cl. H05K 7/20

(52) U.S. Cl. 361/704

(57) ABSTRACT

A pivotally mounted load plate may be provided with downwardly extending protrusions that engage corresponding slots in an integral heat spreader. As a result, when the load plate is rotated onto the integral heat spreader, alignment may be maintained.

### BACKGROUND

This invention relates generally to mounting integrated circuits on circuit boards such as motherboards.

Conventionally, packaged integrated circuits, such as a processor, may be provided through a socket for securement to a printed circuit board such as a motherboard. There are a variety of different ways of making connections between the integrated circuit and the board. One such way is a land grid array, in which surface mount techniques are utilized to connect the socket to the printed circuit board. A load plate may be utilized to force the integrated circuit into tight electrical connection to the socket.

One problem that arises is that the force applied through the load plate may result in relative horizontal movement in the plane of the socket between the load plate and an integral heat spreader provided with the integrated circuit package. This may cause the integrated circuit package to be seated improperly within the socket body. Improper seating may result in open circuits.

Thus, there is a need for better ways to secure packaged integrated circuits to sockets.

### BRIEF DESCRIPTION OF THE DRAWINGS

FIG. 1 is a perspective view of one embodiment of the present invention;

FIG. 2 is an exploded view of the embodiment shown in FIG. 1;

FIG. 3 is a top plan view of one embodiment of the present invention with the load plate removed; and

FIG. 4 is a cross-sectional view taken generally along the line 4-4 in FIG. 1.

### DETAILED DESCRIPTION

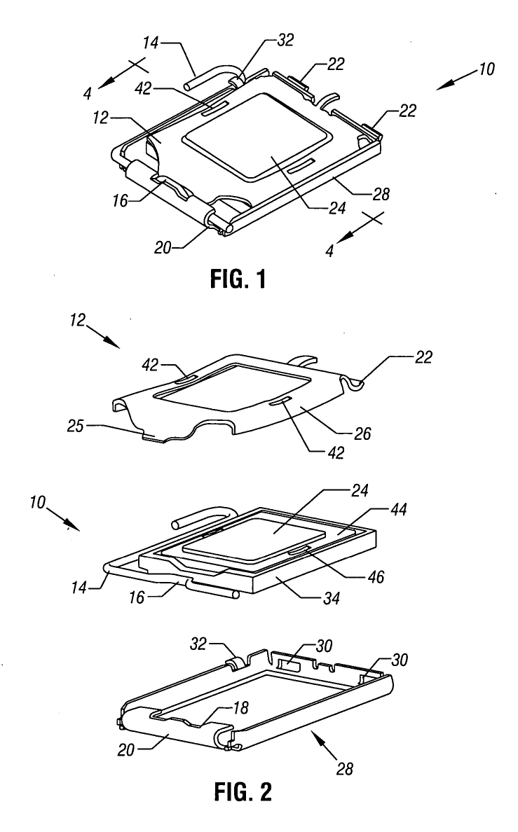

Referring to FIGS. 1 and 2, a land grid array socket assembly 10 may include a packaged integrated circuit 24 held within a socket 34 by a load plate 12. The load plate 12 may hingedly connect to a socket body stiffener 28. The stiffener 28 is secured to the socket 34. To this end, U-shaped clips 22 may be provided on the load plate 12 that engage openings 30 in the socket body stiffener 28. Thus, the load plate 12 may hinge about the openings 30 in the stiffener 28.

The load plate 12 may be cammed downwardly to get good electrical connection between contacts on the integrated circuit 24 and the socket 34 by an actuator 16. The actuator 16, in one embodiment, may be part of an integral L-shaped bar 14, having a curved end that may be latched under a catch 32, in one embodiment, to lock the load plate 12 into engagement with the integrated circuit 24. In particular, the actuator 16 may be rotated counterclockwise around and down as the load lever 14 is rotated within its tubular retainer 20.

Alignment between the load plate 12 and an integral heat spreader 48 may be ensured by downwardly projecting protrusions 42 which engage mating slots 46 in the upper surface of the integral heat spreader 44. When the load plate 12 is a metal stamping, the protrusions 42 may be formed during the stamping process.

Thus, referring to FIG. 2, the socket body stiffener 28 may receive the socket body 34. The stiffener 28 also includes the retainer 20 that secures the load lever 14 to the assembly 10. Thus, the actuator 16 may rotate counterclockwise through about 90 degrees from the closed position, shown in FIG. 2, to an open position.

The packaged integrated circuit 24 may be seated within the integral heat spreader 44. With the load plate 12 clips 22 engaged in the openings 30 in the stiffener 28, the load plate 12 may be rotated counter-clockwise over the integral heat spreader 44. The load lever 14 may be rotated upwardly or counterclockwise from the position shown in FIG. 2. The free end 25 of the load plate 12 may be positioned to be engaged and pressed downwardly by the rotating actuator 16 as the load lever 14 rotates to the position shown in FIGS. 1 and 2, latched under the catch 32.

As all of this is happening, the protrusions 42 and mating slots 46 maintain close alignment between the load plate 12 and the integral heat spreader 44, preventing horizontal displacement between those parts and the packaged integrated circuit 24.

Without the alignment features, such as the slots 46 and protrusions 42, the play between the clips 22 and openings 30 permit relative movement between the load plate 12 and the stiffener 28 towards or away from the retainer 20. Depending on the direction of such horizontal displacement, non-uniform pressure is applied to the socket 34 along the line between the openings 30 and retainer 20. This non-uniform pressure may result in poor electrical connections. The provision of the alignment features keeps the load plate 12 centered over the socket 34 enabling the load plate 12 to apply more uniform pressure to the contacts between the integrated circuit 24 and the socket 34.

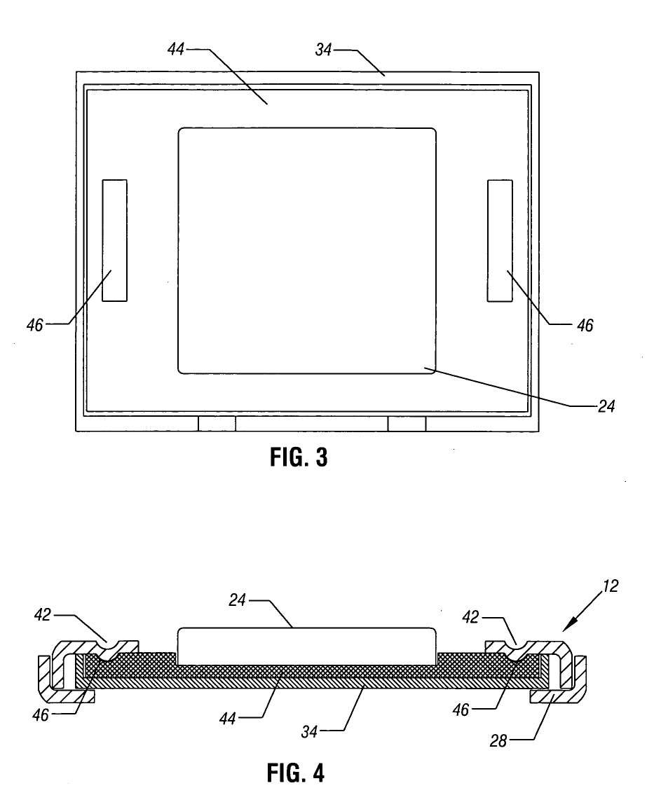

Thus, referring to FIG. 3, the slots 46 in the integral heat spreader 44 are arranged to control horizontal sliding movement during load plate 12 actuation. The slots 46 and protrusions 42 prevent relative movement between the integral heat spreader 44 or integrated circuit package 24 and the load plate 12.

As better shown in FIG. 4, the load plate 12 downward protrusions 46 can engage the upwardly facing slots 46 in the integral heat spreader 44. The socket body stiffener 28 then holds the whole assembly together.

In some embodiments, not only is horizontal movement of the load plate prevented during the socket actuation, reducing the risk of opens caused by improper packaged seating, but the slots 46 in the integral heat spreader 44 may also serve as additional alignment features to ensure that the package 24 is inserted in the right orientation.

While an embodiment is illustrated in which downward protrusions are formed on the load plate and mating slots are formed on the integral heat spreader, other arrangements for alignment features may be utilized as well. For example, the alignment feature on the load plate may be an indentation that receives a protrusion on the integral heat spreader. Other arrangements and orientations of the alignment features may also be possible. Similarly, the number of alignment features may be varied.

While the present invention has been described with respect to a limited number of embodiments, those skilled in the art will appreciate numerous modifications and variations therefrom. It is intended that the appended claims cover all such modifications and variations as fall within the true spirit and scope of this present invention.

1. A method comprising:
providing mating features on a socket load plate and an integral heat spreader to align the load plate and the integral heat spreader.

2. The method of claim 1 including providing a protrusion extending downwardly on said load plate and providing a mating slot on said integral heat spreader.

3. The method of claim 2 including providing a packaged integrated circuit in said integral heat spreader.

4. The method of claim 3 including providing a protrusion on said load plate on each side of said packaged integrated circuit and a mating slot in said integral heat spreader on each side of said packaged integrated circuit.

5. The method of claim 2 including forming said protrusion in said load plate by stamping during the stamping of said load plate.

6. The method of claim 1 including hingedly mounting said load plate on a socket assembly.

7. The method of claim 1 including providing a land grid array socket with said load plate and said integral heat spreader.

8. An integrated circuit socket comprising:
a socket;
a heat spreader mounted on said socket;
a load plate hingedly connected to said socket body; and
said load plate and heat spreader having alignment features to align said heat spreader and said load plate.

9. The socket of claim 8 wherein said load plate is hingedly connected to said socket.

10. The socket of claim 8 wherein said load plate includes at least one downwardly extending protrusion.

11. The socket of claim 10 wherein said integral heat spreader includes at least one depression which mates with said protrusion on said load plate.

12. The socket of claim 11 wherein said integral heat spreader has a central opening, said heat spreader having a depression on each side of said opening, said load plate having an opening and having a protrusion on each side of said load plate opening, said protrusions on said load plate mating with said depressions on said integral heat spreader.

13. The socket of claim 8 including a load lever to cam said load plate into engagement with said integral heat spreader.

14. A method comprising:
enabling a load plate to engage an integral heat spreader in an integrated circuit socket in a first direction; and
preventing relative motion in a direction generally transverse to said first direction between said load plate and said integral heat spreader.

15. The method of claim 14 including providing mating features on said load plate and said integral heat spreader.

16. The method of claim 15 including providing a protrusion extending downwardly on said load plate and providing a mating slot on said integral heat spreader.

17. The method of claim 16 including providing a packaged integrated circuit in said integral heat spreader.

18. The method of claim 17 including providing a protrusion on said load plate on each side of said packaged integrated circuit and a mating slot in said integral heat spreader on each side of said packaged integrated circuit.

19. The method of claim 14 including enabling said load plate to be rotated into engagement with said integral heat spreader.

20. The method of claim 14 including providing a land grid array socket with said load plate and integral heat spreader.
